(19) United States
(12) Patent Application Publication
(10) Pub. No.: US 2009/0078984 A1
(43) Pub. Date: Mar. 26, 2009

(54) SEMICONDUCTOR APPARATUS AND METHOD FOR MANUFACTURING THE SAME

(75) Inventors: Hajime NAGANO, Yokkaichi-shi (JP); Masayuki TANAKA, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/234,190

(22) Filed: Sep. 19, 2008

(30) Foreign Application Priority Data
Sep. 20, 2007 (JP) 2007-243741

(51) Int. Cl. H01L 29/788; H01L 21/28

(52) U.S. Cl. 257/316; 438/591; 257/E29.3; 257/E21.179

(57) ABSTRACT

According to an aspect of the present invention, there is provided a semiconductor apparatus including: a semiconductor substrate; a gate dielectric film that is formed on the semiconductor substrate; a floating gate electrode film that is formed on the gate dielectric film; an inter-gate dielectric film that includes: a metal oxide film that is formed on the floating gate electrode film; an electron trap film that is formed on the metal oxide film; and a silicon oxide film that is formed on the electron trap film; and a control gate electrode film that is formed on the inter-gate dielectric film.

### CROSS-REFERENCE TO RELATED APPLICATIONS

This application claims priority from Japanese Patent Application No. 2007-243741 filed on Sep. 20, 2007, the entire contents of which are incorporated herein by reference.

### BACKGROUND OF THE INVENTION

1. Field of the Invention

An aspect of the present invention relates to a semiconductor apparatus in which a structure including a metal oxide layer is applied as an inter-gate dielectric film between a floating gate electrode film and a control gate electrode film and a method for manufacturing the same.

2. Description of the Related Art

A semiconductor apparatus such as a flash memory device is able to store data without supplying electric power, and hence is widely used as a memory device for a multimedia card. In recent years, increased capacity is demanded and hence higher integration of memory cells is required. Data is written into, erased from, or read from the each memory cell by applying an electric field from a control gate electrode film to a floating gate electrode film. Normally, an inter-gate dielectric film is formed between the control gate electrode film and the floating gate electrode film that accumulates electric charges.

In order to achieve the high-integration of the memory cells, it is necessary to reduce design rules. Generally, when the design rules are reduced, the electric field applied to the inter-gate dielectric film is strengthened. Therefore, in the related art, when the design rules are reduced, charge holding characteristics of the inter-gate dielectric film is deteriorated and desired element characteristics cannot be obtained. In order to maintain the charge holding characteristic to a desirable level, it is proposed to apply metal oxide having a high dielectric constant characteristic to at least part of the inter-gate dielectric film (For example, see JP-2006-310662-A). By using a material having a high permittivity, the thickness of the inter-gate dielectric film can be increased while keeping the electric characteristic.

Since the leak current is restrained by thickening the inter-gate dielectric film, the element performance is improved by replacing the material.

Although various materials are considered as the inter-gate dielectric film, it is studied to configure the same by laminating a silicon oxide film, a silicon nitride film, and an aluminum oxide film in sequence from below (For example, see JP-2006-86525-A). The reason why the silicon oxide film is formed is that the silicon oxide film is stable in electric characteristics in comparison with the metal oxide, and hence the physical film thickness may be secured, so that the leak current is restrained. However, when the silicon oxide film is formed after having formed the metal oxide layer, the metal oxide layer is damaged during the manufacture of the silicon oxide film, and metal-oxygen coupling may be disconnected. Further, impurities stayed in the metal oxide layer is dispersed in the area in which the floating gate electrode film is formed due to the influence of material gas for forming the silicon oxide film, so that the element characteristics are difficult to control to the desired characteristics.

### SUMMARY OF THE INVENTION

According to an aspect of the present invention, there is provided a semiconductor apparatus including: a semiconductor substrate; a gate dielectric film that is formed on the semiconductor substrate; a floating gate electrode film that is formed on the gate dielectric film; an inter-gate dielectric film that includes: a metal oxide film that is formed on the floating gate electrode film; an electron trap film that is formed on the metal oxide film; and a silicon oxide film that is formed on the electron trap film; and a control gate electrode film that is formed on the inter-gate dielectric film.

According to another aspect of the present invention, there is provided a method for manufacturing a semiconductor apparatus, the method including: forming a gate dielectric film on a semiconductor substrate; forming a floating gate electrode film on the gate dielectric film; forming an inter-gate dielectric film: by forming a metal oxide film on the floating gate electrode film; by forming an electron trap film on the metal oxide film; and by forming a silicon oxide film on the electron trap film; and forming a control gate electrode film on the inter-gate dielectric film.

According to still another aspect of the present invention, there is provided a semiconductor apparatus including: a semiconductor substrate; a gate dielectric film that is formed on the semiconductor substrate; a floating gate electrode film that is formed on the gate dielectric film; an inter-gate dielectric film that includes: a first silicon nitride film that is formed on the floating gate electrode film; a first silicon oxide film that is formed on the first silicon nitride film; a metal oxide film that is formed on the first silicon oxide film; a second silicon nitride film that is formed on the metal oxide film; a second silicon oxide film that is formed on the second silicon nitride film; and a third silicon nitride film that is formed on the second silicon oxide film; and a control gate electrode film that is formed on the inter-gate dielectric film.

### BRIEF DESCRIPTION OF THE DRAWINGS

Embodiment may be described in detail with reference to the accompanying drawings, in which:

FIG. 1 is a schematic drawing showing a structure in plan view of a memory cell area according to an embodiment of the present invention;

FIG. 2A is a schematic cross-sectional view taken along the word line direction (cross-sectional view taken along the line A-A in FIG. 1);

FIG. 2B is an enlarged view of a portion B in FIG. 2A;

FIG. 2C is a schematic cross-sectional view taken along the bit line direction (cross-sectional view taken along the line C-C in FIG. 1);

FIG. 3 is a schematic cross-sectional view showing a manufacturing step (No. 1);

FIG. 4 is a schematic cross-sectional view showing a manufacturing step (No. 2);

FIG. 5 is a schematic cross-sectional view showing a manufacturing step (No. 3);

FIG. 6 is a schematic cross-sectional view showing a manufacturing step (No. 4);

FIG. 7 is a schematic cross-sectional view showing a manufacturing step (No. 5);

FIG. 8 is a schematic cross-sectional view showing a manufacturing step (No. 6);

FIG. 9 is a schematic cross-sectional view showing a manufacturing step (No. 7);

FIG. 10 is a schematic cross-sectional view showing a manufacturing step (No. 8);

FIG. 11 is a schematic cross-sectional view showing a manufacturing step (No. 9); and

FIG. 12 is a schematic cross-sectional view showing a manufacturing step (No. 10).

### DETAILED DESCRIPTION OF THE INVENTION

Referring now to the drawings, an embodiment in which the present invention is applied to a non-volatile semiconductor storage apparatus will be described. In the drawing to be referred to below, the same or similar parts are designated by the same or similar reference numerals. The drawings are shown only schematically and the relation between the thickness and the dimensions in plan view and the ratio among the respective layers are different from the actual thickness, dimensions and ratio.

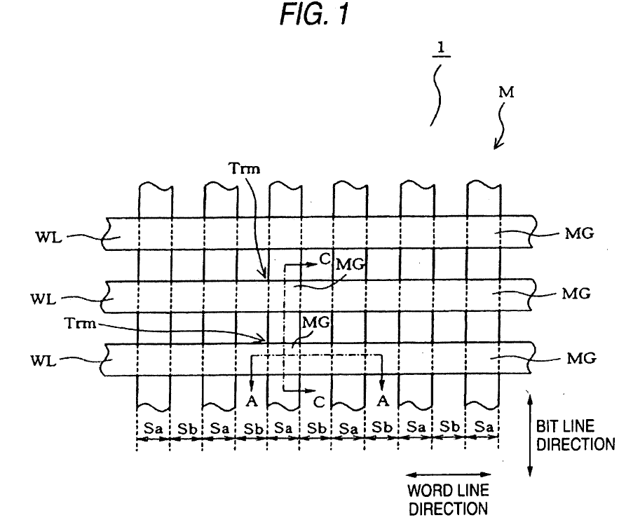

FIG. 1 shows a plan view of a memory cell area in a non-volatile semiconductor storage apparatus 1.

As shown in FIG. 1, in a memory cell area M, a plurality of memory cell transistors Trm are arranged in the word line direction and the bit line direction in a matrix form, and a peripheral circuit (not shown) to read, write, and delete data stored in the memory cell transistors Trm is adapted. As the non-volatile semiconductor storage apparatus having the memory cell structure as described above, there is a NAND-type flash memory device having a cell unit structure in which a plurality of memory cell transistors connected between two selection gate transistors in series.

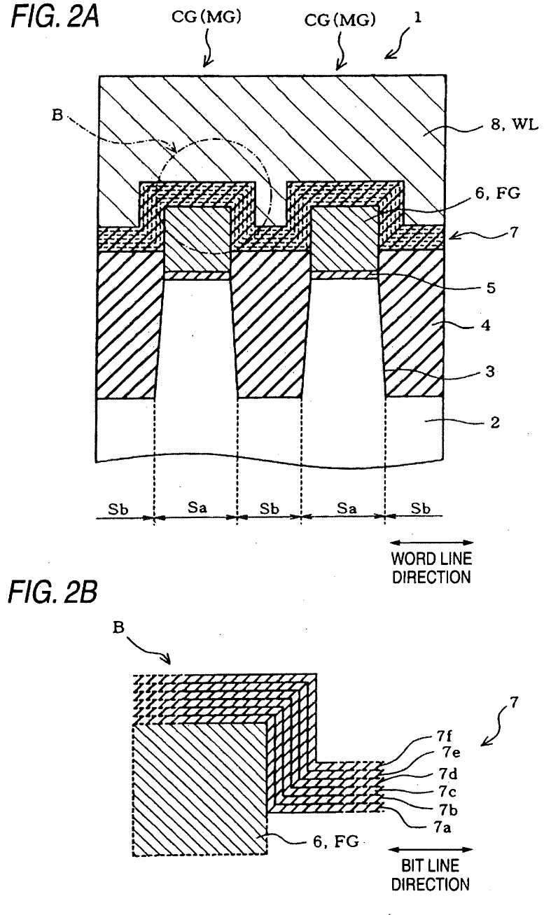

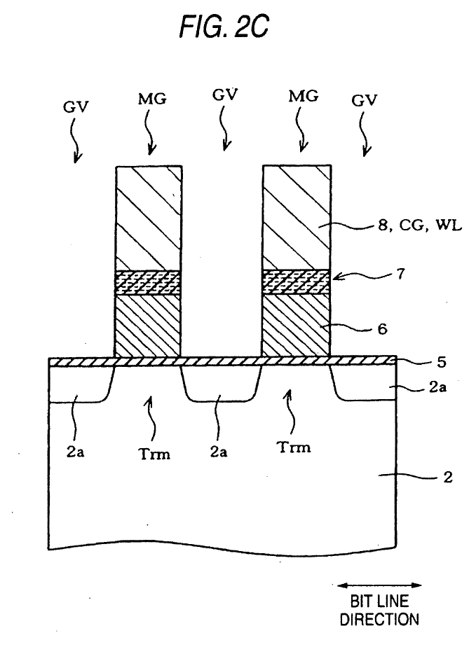

FIG. 2A is a cross-sectional view of the respective memory cells taken along the word line direction (cross-sectional view taken along the line A-A in FIG. 1), and FIG. 2B is an enlarged cross-sectional view of a portion B in FIG. 2A. FIG. 2C is a cross-sectional view of the respective memory cells taken along the bit line direction (cross-sectional view taken along the line C-C in FIG. 1). As shown in FIG. 2A, a well (not shown) is formed on an upper portion of a P-type silicon substrate 2, and a plurality of element isolation grooves 3 are formed on the silicon substrate 2. The element isolation grooves 3 are formed so as to isolate a plurality of active areas Sa in the word line direction in FIG. 2A. Formed in the element isolation grooves 3 are element isolation dielectric films 4. Upper portions of the element isolation dielectric films 4 project upward from a surface of the silicon substrate 2.

On the other hand, gate dielectric films 5 are formed respectively on the plurality of active areas Sa of the silicon substrate 2. The gate dielectric film 5 is formed, for example, of a silicon oxide film. The gate dielectric films 5 come into contact at the side surfaces thereof with part of side surfaces of upper portions of the element isolation dielectric films 4. The gate dielectric films 5 are formed with floating gate electrode films FG on the surface thereof. The floating gate electrode films FG are formed of polycrystalline silicon doped with impurities such as phosphorous. The floating gate electrode films FG are disposed so as to come in contact with the side surfaces of the upper portions of the element isolation dielectric films 4 and project upward with respect to upper ends of the element isolation dielectric films 4.

The side surface of the upper portions of the element isolation dielectric films 4 projecting upward from the silicon substrate 2 are formed to be flush with side surfaces of the gate dielectric films 5 and side surfaces of lower portions of the floating gate electrode films FG. The element isolation dielectric films 4 are formed, for example, of silicon oxide films.

An inter-gate dielectric film 7 is formed along upper surfaces of the element isolation dielectric films 4, side surfaces of upper portions of the floating gate electrode films FG, and upper surfaces of the floating gate electrode films FG. As shown by an enlarged view in FIG. 2B, the inter-gate dielectric film 7 includes, from the lower layer side (on the side of the upper surfaces of the element isolation dielectric films 4 and the side surfaces and the upper surfaces of the floating gate electrode films FG) to the upper layer side, a silicon nitride film 7a/a silicon oxide film 7b/a high-permittivity film 7c/a silicon nitride film 7d/a silicon oxide film 7e/a silicon nitride film 7f in this sequence. The silicon nitride film 7d functions as an electron trap film and a film for preventing passage of chlorine.

Formed directly on the floating gate electrode films FG is the silicon nitride film 7a. The silicon oxide film 7b is formed directly on the silicon nitride film 7a, the high-permittivity film 7c is formed directly on the silicon oxide film 7b, the silicon nitride film 7d is formed directly on the high-permittivity film 7c, the silicon oxide film 7e is formed directly on the silicon nitride film 7d and the silicon nitride film 7f is formed directly on the silicon oxide film 7e. The high-permittivity film 7c is formed of an aluminum oxide (Al₂O₃) film as a metal oxide layer.

A conductive layer 8 is formed on the inter-gate dielectric film 7 along the word line direction as word lines WL. The word lines WL are configured to connect a control gate electrode film CG of the individual memory cell transistors Trm. The conductive layer 8 is formed, for example, of a polycrystalline silicon layer and a tungsten silicide layer formed directly on the polycrystalline silicon layer. In this manner, a gate electrode MG of the memory cell transistor Trm is formed into a laminated structure including the floating gate electrode film FG, the inter-gate dielectric film 7, and the control gate electrode film CG. In stead of the tungsten silicide layer, other kinds of silicide layers, such as a cobalt silicide layer, may be used.

As shown in FIG. 2C, the gate electrodes MG of the memory cell transistors Trm are arranged in parallel in the bit line direction, and are electrically isolated by dividing areas GV. Although not shown, an inter-layer dielectric film and a barrier film for preventing passage of impurities are formed in the respective dividing areas GV.

Source/drain areas 2a are formed on the surface layer of the silicon substrate 2 on both sides of the gate electrodes MG of the memory cell transistors Trm. The memory cell transistors Trm each include the gate dielectric film 5, the gate electrode MG, and the source/drain area 2a.

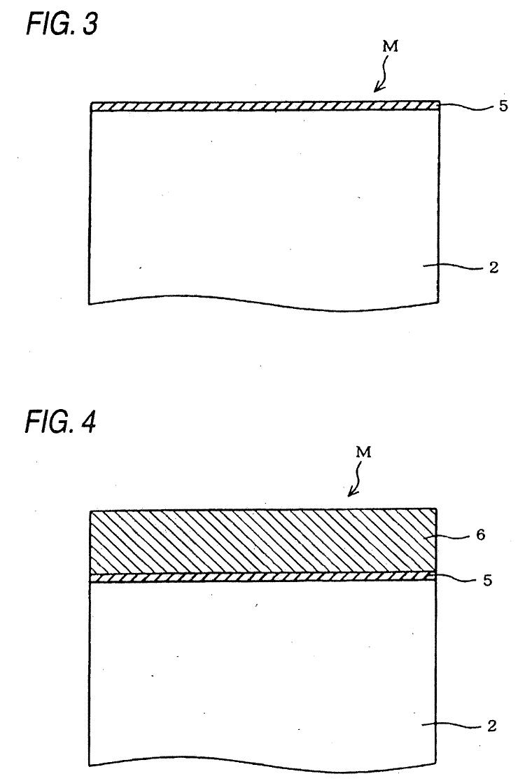

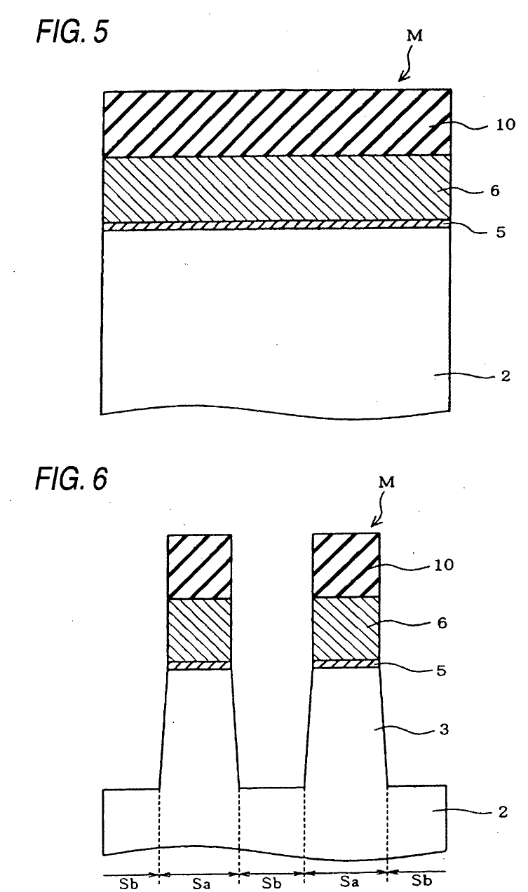

Referring now to FIG. 3 to FIG. 12, a method for manufacturing the configuration described above will be described. As shown in FIG. 3, the gate dielectric film 5 serving as a tunnel dielectric film is formed on the silicon substrate 2 by a thermal oxidation. Then, as shown in FIG. 4, a polycrystalline silicon layer 6 doped with impurities such as phosphorous is laminated on the gate dielectric films 5 by a CVD (chemical vapor deposition) method. Then, as shown in FIG. 5, a mask film 10 formed of a silicon nitride film is laminated on the polycrystalline silicon layer 6. Then, a resist (not shown) is applied on the mask film 10 and is patterned, and the mask film 10, the polycrystalline silicon layer 6, the gate dielectric films 5, and an upper portion of the silicon substrate 2 are etched in sequence using the patterned resist film, so that the element isolation grooves 3 are formed on the silicon substrate 2. Accordingly, the active areas Sa and element isolation areas Sb are sectionalized.

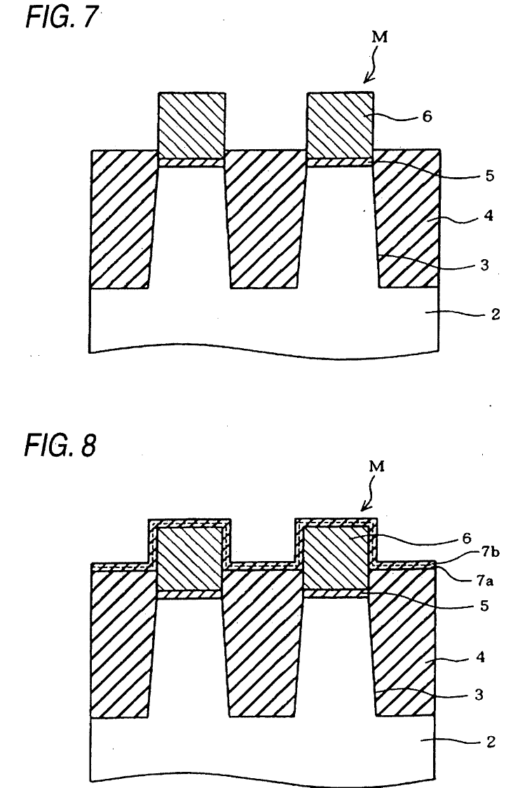

Subsequently, as shown in FIG. 7, the resist mask is peeled, a silicon oxide film is laminated on the mask film 10 and in the element isolation grooves 3 as the element isolation dielectric film 4, and the mask film 10 is flattened by a CMP method as a stopper, so that the element isolation dielectric film 4 on the mask film 10 is removed, and the mask film 10 is etched with chemical solution or the like to expose an upper surface of the polycrystalline silicon layer 6. Subsequently, an upper portion of the element isolation dielectric film 4 is removed with rare hydrofluoric acid solution, and side surfaces of upper portions of the polycrystalline silicon layer 6 are exposed.

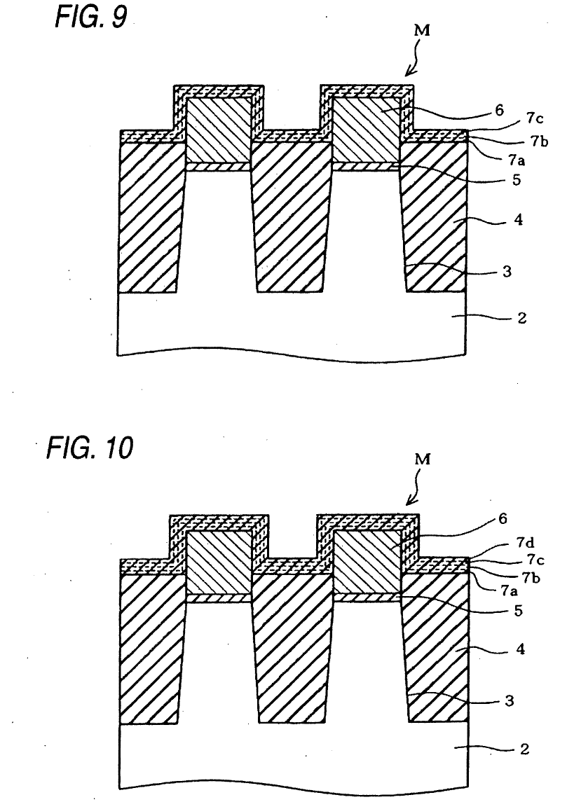

Then, as shown in FIG. 8, the silicon nitride film 7a is formed along the exposed upper surfaces and the exposed side surfaces of the polycrystalline silicon layer 6 and an upper surface of the element isolation dielectric films 4 by the CVD method or a radical nitriding, and the silicon oxide film 7b is laminated on the silicon nitride film 7a by the CVD method. Then, as shown in FIG. 9, the high-permittivity film 7c is laminated on an upper surface and outer side surfaces of the silicon oxide film 7b by the CVD method, a spatter method or an ALD (Atomic Layer Deposition) method.

Then, as shown in FIG. 10, the silicon nitride film 7d is formed with material gas which does not contain chlorine (Cl). More specifically, it is formed by using BTBAS (BisTertialButylAminoSilane) as a material gas for silicon and NH₃ as a material gas for nitride by the CVD method. At this time point, if the film is formed using gas containing chlorine (for example, dichlorosilane (SiH₂Cl₂) or the like) as a material gas, coupling between metal and oxygen of the aluminum oxide film 7c may be disconnected by the influence of chlorine. Therefore, at this time point, the material gas which does not contain chlorine is used for film formation.

In a step described later, the silicon nitride film 7f is formed using dichlorosilane (SiH₂Cl₂) gas. Although chlorine (Cl) is contained in the dichlorosilane gas, the silicon nitride film 7d can be formed to have an enough thickness to prevent passage of chlorine (Cl).

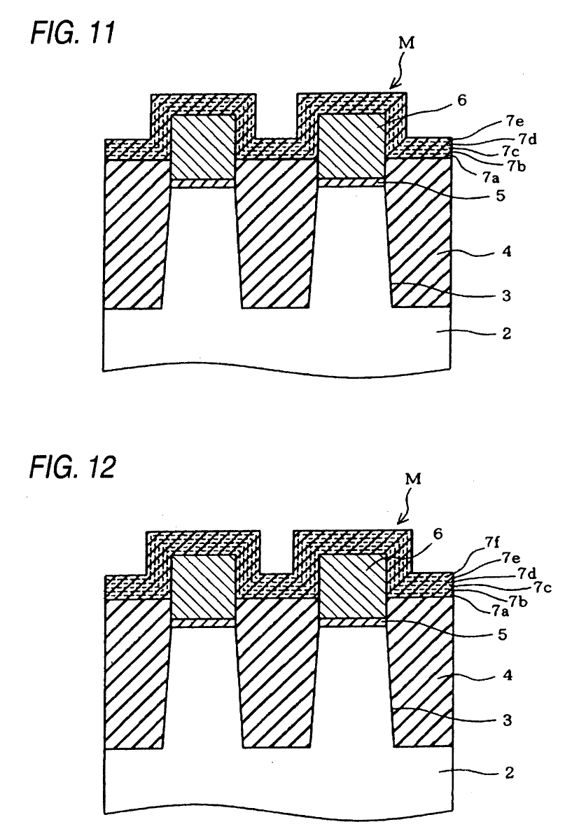

Then, as shown in FIG. 11, the silicon oxide film 7e is formed entirely on the silicon nitride film 7d by the CVD method. Then, as shown in FIG. 12, the silicon nitride film 7f is formed on the silicon oxide film 7e using dichlorosilane (SiH₂Cl₂) gas by the CVD method.

Then, as shown in FIG. 2A, the conductive layer 8 is formed on the silicon nitride film 7f. The conductive layer 8 has a laminated structure including, for example, a polycrystalline silicon layer and a tungsten silicide layer, and is formed as the control gate electrode film CG. Subsequently, a mask pattern is formed on the conductive layer 8, and an anisotropic etching is performed to divide and isolate the respective films 6 to 8 in the direction orthogonal to the paper surface of FIG. 2A (the direction orthogonal to the word line direction). Detailed description of which will be omitted.

The silicon nitride film 7d is able to trap electrons unlike to, for example, the silicon oxide film, and hence a self electric field to be applied may be weakened, whereby the electric field is alleviated. According to this embodiment, since the silicon nitride film 7d is formed directly on the high-permittivity film 7c, a leak current at the time of application of a high-electric field may be restrained as compared with the case, for example, in which only the silicon oxide film 7e is applied to the high-permittivity film 7c. Accordingly, the element characteristics may be controlled to desired characteristics.

Since the silicon nitride film 7d is formed directly on the high-permittivity film 7c by using the material gas which does not contain chlorine, the silicon nitride film 7d does not disconnect metal-oxygen coupling in the high-permittivity film 7c. Accordingly, the element characteristics may be controlled to desired characteristics.

Since the silicon nitride film 7d serving as the film for preventing passage of chlorine is formed directly on the high-permittivity film 7c, the material gas used to form the silicon oxide film 7e does not come into contact with the high-permittivity film 7c, so that disconnection of the metal-oxygen coupling in the high-permittivity film 7c may be restrained. Also, even when the silicon nitride film 7f is formed using dichlorosilane (SiH₂CL₂) gas, the dichlorosilane gas does not come into direct contact with the high-permittivity film 7c by the action of the silicon nitride film 7d to prevent passage of chlorine.

Accordingly, the problems of quality deterioration of the high-permittivity film 7c and the dispersion of impurities are solved. Therefore, deterioration of the element structure is prevented, and necessity to provide additional processes to recover the deterioration is eliminated. Accordingly, the element characteristics may be controlled to desired characteristics.

### OTHER EMBODIMENTS

The present invention is not limited to the embodiment shown above and, for example, the following modifications and expansions may be made.

The laminated structure including, from the lower layer side, the silicon nitride film 7a/the silicon oxide film 7b/the high-permittivity film 7c/the silicon nitride film 7d/the silicon oxide film 7e/the silicon nitride film 7f in this sequence is employed as the inter-gate dielectric film 7. However, the present invention is not limited thereto, and as long as the silicon nitride film 7d is formed directly on the upper layer side of the high-permittivity film 7c, any structure can be applied. For example, as the structure of the upper layer side of the silicon nitride film 7d, a single layer structure of the silicon oxide film, a single layer structure of the silicon nitride film, or a laminated structure thereof may be applied. In other words, as long as the silicon nitride film 7d formed with the material gas that does not contain chlorine is formed directly on the upper layer side of the high-permittivity film 7c, a structure in which the silicon nitride film 7f formed with dichlorosilane gas as the material gas is formed directly on the silicon nitride film 7d, and a silicon oxide film such as the silicon oxide film 7e is formed directly on the silicon nitride film 7f can be applied.

Although the embodiment in which the silicon nitride film 7f is formed using dichlorosilane (SiH₂Cl₂) gas has been described, film may be formed using other material gases containing chlorine, such as trichlorosilane (SiHCl₃) gas or tetrachlorosilane (SiCl₄) gas.

Either the silicon oxide film or the silicon nitride film may be formed directly on the lower layer side of the high-permittivity film 7c, and a single layer of the silicon oxide film or the silicon nitride film, or a laminated structure including the both films may be employed on the lower layer side of the high-permittivity film 7c. These structures may be selected as needed according to the characteristics of the device.

Although the embodiment in which the aluminum oxide (Al₂O₃) film is used as the high-permittivity film 7c has been described, other metal oxide layer (for example, an oxide film of zirconium (Zr) or an oxide film of hafnium (Hf)) may be applied. Either the single element oxide film or the oxide film containing a plurality of types of metals may be applied from the above-described elements. These structures may also be selected as needed according to the characteristics of the device.

In the embodiment, the silicon nitride film 7d directly on the high-permittivity film 7c is formed using BTBAS (BisTertButylAminoSilane) gas as the material gas for silicon and using NH₃ as the material gas for nitride. However, the film may be formed using other material gasses as long as the material gas which does not contain chlorine.

The silicon nitride film 7f may be formed by the radial nitriding. The electron trap film is not limited to the silicon nitride film, and it must simply be a dielectric film containing nitride such as the silicon oxynitride film.

According to an aspect of the present invention, disconnection of the metal-oxygen coupling in the metal oxide is restrained and desired device characteristics are achieved.

What is claimed is:

1. A semiconductor apparatus comprising:
a semiconductor substrate;
a gate dielectric film that is formed on the semiconductor substrate;
a floating gate electrode film that is formed on the gate dielectric film;
an inter-gate dielectric film that comprises:
a metal oxide film that is formed on the floating gate electrode film;
an electron trap film that is formed on the metal oxide film; and
a silicon oxide film that is formed on the electron trap film; and
a control gate electrode film that is formed on the inter-gate dielectric film.

2. The semiconductor apparatus according to claim 1,
wherein the electron trap film is formed of a material that is differ from materials of the silicon oxide film and the metal oxide film.

3. The semiconductor apparatus according to claim 1,
wherein the electron trap film includes a silicon nitride film.

4. The semiconductor apparatus according to claim 1,
wherein the electron trap film includes a silicon oxynitride film.

5. The semiconductor apparatus according to claim 1,
wherein the electron trap film prevents chlorine from entering into the metal oxide film.

6. The semiconductor apparatus according to claim 1,
wherein the electron trap film prevents a metal-oxygen coupling in the metal oxide film from being disconnected by chlorine, when the silicon oxide film is formed.

7. The semiconductor apparatus according to claim 1,
wherein, when a high electric field is applied, the electron trap film traps electrons thereby weakening the electric field applied thereto and suppressing a leak current.

8. A method for manufacturing a semiconductor apparatus, the method comprising:
forming a gate dielectric film on a semiconductor substrate;
forming a floating gate electrode film on the gate dielectric film;
forming an inter-gate dielectric film:
by forming a metal oxide film on the floating gate electrode film;
by forming an electron trap film on the metal oxide film; and
by forming a silicon oxide film on the electron trap film; and
forming a control gate electrode film on the inter-gate dielectric film.

9. The method according to claim 8,
wherein the step of forming the electron trap film includes forming a dielectric film containing nitride directly on the metal oxide film by use of a material gas that does not contain chlorine.

10. The method according to claim 8,
wherein the step of forming the electron trap film includes forming a silicon nitride film by use of a BTBAS gas and an NH₃ gas.

11. The method according to claim 8,
wherein the step of forming the electron trap film includes forming a silicon nitride film by performing a radial nitriding process.

12. A semiconductor apparatus comprising:
a semiconductor substrate;
a gate dielectric film that is formed on the semiconductor substrate;
a floating gate electrode film that is formed on the gate dielectric film;
an inter-gate dielectric film that comprises:
a first silicon nitride film that is formed on the floating gate electrode film;
a first silicon oxide film that is formed on the first silicon nitride film;
a metal oxide film that is formed on the first silicon oxide film;
a second silicon nitride film that is formed on the metal oxide film;
a second silicon oxide film that is formed on the second silicon nitride film; and
a third silicon nitride film that is formed on the second silicon oxide film; and
a control gate electrode film that is formed on the inter-gate dielectric film.
